(19) United States
(12) Patent Application Publication
(10) Pub. No.: US 2022/0165578 A1
(43) Pub. Date: May 26, 2022

(54) SUBSTRATE PROCESSING METHOD AND SUBSTRATE PROCESSING APPARATUS

(71) Applicant: Tokyo Electron Limited, Tokyo (JP)

(72) Inventors: Maju TOMURA, Miyagi (JP); Satoshi OHUCHIDA, Miyagi (JP); Yoshihide KIHARA, Miyagi (JP)

(73) Assignee: Tokyo Electron Limited, Tokyo (JP)

(21) Appl. No.: 17/398,013

(22) Filed: Aug. 10, 2021

Related U.S. Application Data
(60) Provisional application No. 63/118,340, filed on Nov. 25, 2020.

(51) Int. Cl. H01L 21/311; H01L 21/683; H01J 37/32

(52) U.S. Cl. CPC H01L 21/31116; H01L 21/6831; H01J 37/32522; H01J 2237/2007; H01J 37/32449; H01J 37/32082; H01J 2237/334; H01J 37/32724

(57) ABSTRACT

A method including providing a substrate in a process chamber of a substrate processing apparatus, the substrate having a first region containing a silicon oxide film and a second region containing a film other than the silicon oxide film; adsorbing hydrogen fluoride on the substrate; and exposing the substrate with the absorbed hydrogen fluoride to plasma generated from an inert gas to selectively etch the first region with respect to the second region.

### CROSS-REFERENCE TO RELATED APPLICATION

This application is related to U.S. Provisional Application Ser. No. 63/118,340 filed on Nov. 25, 2020, the entire contents of which is incorporated by reference herein.

### BACKGROUND

### Technical Field

The present disclosure relates to semiconductor manufacturing equipment and is generally directed to a method and an apparatus for processing substrates. More particularly, the present disclosure relates to a method of selectively etching a first region containing a silicon oxide film with respect to a second region containing a film other than silicon oxide.

### BACKGROUND

In conventional methods for processing substrates, when selective etching of a substrate with a first region containing a silicon oxide film with respect to a second region containing a film other than silicon oxide is performed, an initial step is a fluorocarbon (CF) deposition process on both the first region and the second region, and thereafter an etching process is performed. During the etching process, the first region and the second region are both etched. The present inventors have recognized that the use of CF gas creates possible clogging on the surface of the substrate that is being etched. Clogging occurs when residual CF builds up on portions of the surface of the first region that is being processed.

### SUMMARY

An exemplary embodiment is disclosed which provides a method including providing a substrate in a process chamber of a substrate processing apparatus, the substrate having a first region containing a silicon oxide film and a second region containing a film other than the silicon oxide film; adsorbing hydrogen fluoride on the substrate; and exposing the substrate with the absorbed hydrogen fluoride to plasma generated from an inert gas to selectively etch the first region with respect to the second region.

In another exemplary embodiment, a substrate processing apparatus is configured to perform processing on a substrate to modify a condition of the substrate. The substrate processing apparatus includes: a process chamber, a substrate support, including an ESC, that supports a substrate having a first region containing a silicon oxide film and a second region containing a film other than the silicon oxide film; and processing circuitry. The processing circuitry is configured to control providing of fluoride inside the process chamber so the substrate absorbs the hydrogen fluoride, and control providing of plasma generated from an inert gas inside the process chamber to expose the substrate with the absorbed hydrogen fluoride to the generated plasma to selectively etch the first region with respect to the second region.

The foregoing paragraphs have been provided by way of general introduction, and are not intended to limit the scope of the following claims. The described embodiments, together with further advantages, will be best understood by reference to the following detailed description taken in conjunction with the accompanying drawings.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1A is an exemplary embodiment of selective etching of a silicon oxide film with respect to a silicon nitride film.

FIG. 1B is an exemplary graph showing a gas flow and time relationship used in the process of FIG. 1A.

FIG. 2A is an exemplary embodiment of selective etching of a silicon oxide film with respect to a silicon nitride film using hydrogen fluoride (HF) gas adsorption.

FIG. 2B is an exemplary graph showing a gas flow and radio frequency (RF) power relationship versus time used in the process of FIG. 2A.

FIG. 2C is an exemplary graph showing a relationship between a number of etch cycles and the etch amount for the process of FIG. 2A.

FIG. 3 is an exemplary graph showing an HF absorption curve produced during an experiment in comparison to HF absorption curve data from a manual or handbook.

FIG. 4 is a flowchart illustrating a method in accordance with an exemplary embodiment.

FIG. 5A illustrates a state of an exemplary substrate during the method of FIG. 4.

FIG. 5B illustrates a state of the exemplary substrate during the method of FIG. 4.

FIG. 5C illustrates a state of the exemplary substrate during the method of FIG. 4.

FIG. 5D illustrates a state of the exemplary substrate during the method of FIG. 4.

FIG. 5E illustrates a state of the exemplary substrate during the method of FIG. 4.

FIG. 6A illustrates a state of another exemplary substrate during the method of FIG. 4.

FIG. 6B illustrates a state of the other exemplary substrate during the method of FIG. 4.

FIG. 6C illustrates a state of the other exemplary substrate during the method of FIG. 4.

FIG. 7 is diagram of an exemplary capacitively coupled plasma (CCP) type plasma system.

FIG. 8 is a block diagram of a computer-based system used to control processes performed in embodiments according to the present disclosure.

### DETAILED DESCRIPTION

The description set forth below in connection with the appended drawings is intended as a description of various embodiments of the disclosed subject matter and is not necessarily intended to represent the only embodiment(s). In certain instances, the description includes specific details for the purpose of providing an understanding of the disclosed subject matter. However, it will be apparent to those skilled in the art that embodiments may be practiced without these specific details. In some instances, well-known structures and components may be shown in block diagram form in order to avoid obscuring the concepts of the disclosed subject matter.

Reference throughout the specification to “one embodiment” or “an embodiment” means that a particular feature, structure, characteristic, operation, or function described in connection with an embodiment is included in at least one embodiment of the disclosed subject matter. Thus, any appearance of the phrases “in one embodiment” or “in an embodiment” in the specification is not necessarily referring to the same embodiment. Furthermore, references to “one embodiment” of the present invention are not intended to be interpreted as excluding the existence of additional embodiments that also incorporate the recited features. Further, the particular features, structures, characteristics, operations, or functions may be combined in any suitable manner in one or more embodiments. Further, it is intended that embodiments of the disclosed subject matter can and do cover modifications and variations of the described embodiments. It must be noted that, as used in the specification and the appended claims, the singular forms “a,” “an,” and “the” include plural referents unless the context clearly dictates otherwise. That is, unless clearly specified otherwise, as used herein the words “a” and “an” and the like carry the meaning of “one or more.” Additionally, it is to be understood that terms such as “left,” “right,” “top,” “bottom,” “front,” “rear,” “side,” “height,” “length,” “width,” “upper,” “lower,” “interior,” “exterior,” “inner,” “outer,” and the like that may be used herein, merely describe points of reference and do not necessarily limit embodiments of the disclosed subject matter to any particular orientation or configuration. Furthermore, terms such as “first,” “second,” “third,” etc., merely identify one of a number of portions, components, points of reference, operations and/or functions as described herein, and likewise do not necessarily limit embodiments of the disclosed subject matter to any particular configuration or orientation.

An exemplary substrate processing method of the present disclosure is a method for etching a first region including a silicon oxide film selectively with respect to a second region including a film other than the silicon oxide film by performing plasma processing of a substrate. The method includes providing a substrate including the first region and the second region; causing hydrogen fluoride to be adsorbed on the substrate; and exposing the substrate having the adsorbed hydrogen fluoride to plasma generated from an inert gas to etch the first region selectively with respect to the second region.

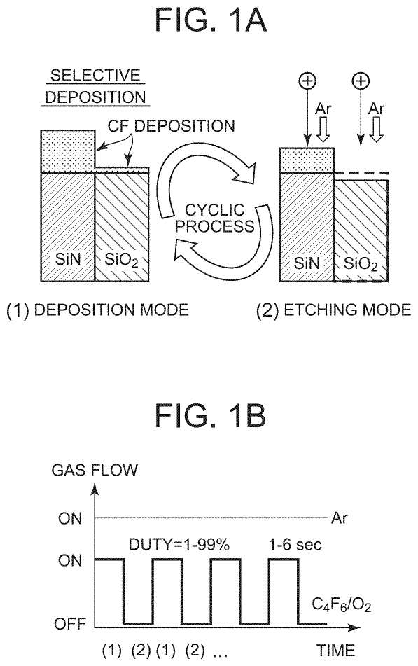

FIG. 1A is an exemplary embodiment of a conventional process of selective etching of a silicon oxide film with respect to a silicon nitride film. FIG. 1A shows a substrate W with a silicon nitride film and a silicon oxide film that is adjacent to the silicon nitride film. As seen in FIG. 1A, a first step in the conventional process is a selective deposition mode (indicated by “(1) Deposition Mode” or “(1)” in the FIGS. 1A and 1B). During this mode, CF is deposited on the top surface of the silicon oxide film and the silicon nitride film. A larger amount of CF is deposited on the silicon nitride film than on the silicon oxide film, resulting in a thicker layer of CF on the silicon nitride film than on the silicon oxide film. Exemplary processing conditions during the deposition mode are a chamber 1 pressure of 30 mTorr, 500 W RF power for plasma generation (continuous wave), 100 W RF power for biasing (continuous wave), and the ratio of C₄F₆/Ar/O₂ is 16/1000/10 standard cubic centimeters per minute (sccm).

After the deposition mode is performed, an etching mode is performed (indicated by “(2) Etching Mode” or “(2)” in the FIGS. 1A and 1B). In the etching mode, the silicon nitride film and the silicon oxide film are subjected to Argon (Ar) gas for a period of time (e.g., 3-5 seconds). As seen in FIG. 1A, exposure to the Ar gas causes the thickness of the deposited CF material to be reduced by a particular thickness amount. The original thickness of the silicon nitride film is not affected (i.e., the silicon nitride film is not etched). Also, as seen in FIG. 1A, the total thickness of material removed from the left side of the substrate W having the silicon nitride film is substantially similar to the total thickness of material removed from the right side of the substrate having the silicon oxide film. That is, the total thickness of the deposited CF removed from the left side of the substrate is substantially similar to the total thickness of the deposited CF removed from the right side of the substrate W and the thickness of silicon oxide film removed from the right side of the substrate W. However, there is also an SiOF layer located between the CF film and the silicon oxide film, and it is in a state where it easily volatizes even with low ion energy during the etching mode. The deposition mode and etching mode are performed as one cycle, and several cycles can be repeated to obtain a desired amount of material removed from the substrate W.

FIG. 1B is an exemplary graph showing a gas flow and time relationship used in the conventional process of FIG. 1A. As seen in FIG. 1B, the Ar gas is continuously provided during the deposition modes and etching modes of FIG. 1A. The duty cycle can be 1-99 percent, and the period in which the C₄F/O₂ is applied can be between, for example, 1 and 6 seconds. In the conventional process of FIG. 1A, when the length of the deposition mode is 3 seconds, and the length of the etching mode is 3 seconds, the selectivity of etching is high, but clogging occurs. When the length of the deposition mode is 1 second, and the length of the etching mode is 5 seconds, the selectivity of etching is low, but clogging does not occur.

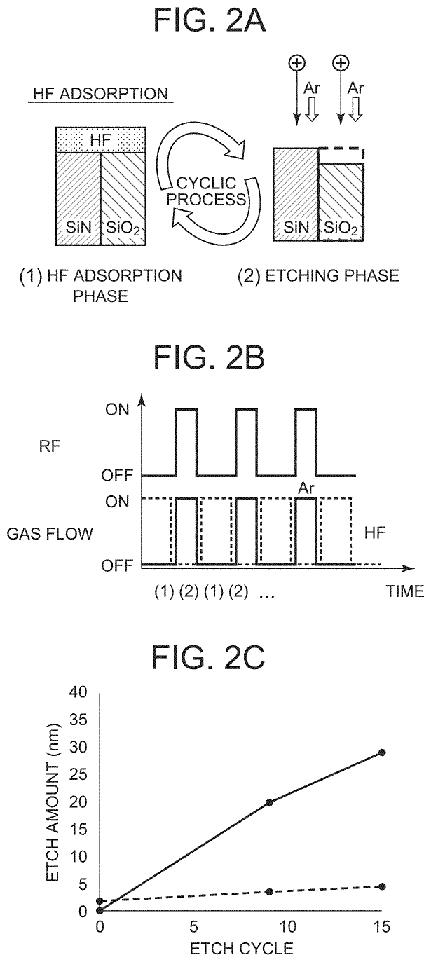

FIGS. 2A, 2B, and 2C illustrate an exemplary embodiment of a process of selective etching of a silicon oxide film with respect to a silicon nitride film according to the present disclosure. FIG. 2A is an exemplary embodiment of selective etching of a silicon oxide film with respect to a silicon nitride film using HF gas adsorption. FIG. 2A shows a similar substrate W to FIG. 1A in which the substrate W has a silicon nitride film, and a silicon oxide film is adjacent to the silicon nitride film. As seen in FIG. 2A, the process includes an HF adsorption phase (indicated by “(1) HF adsorption phase” or “(1)” in the FIGS. 2A and 2B) and an etching phase (indicated by “(2) Etching phase” or “(2)” in the FIGS. 2A and 2B). The method includes a first step of providing a substrate W, a second step of causing HF to be adsorbed on the substrate W, and a third step of exposing the substrate W having the adsorbed HF to plasma generated from an inert gas to etch the first region selectively with respect to the second region.

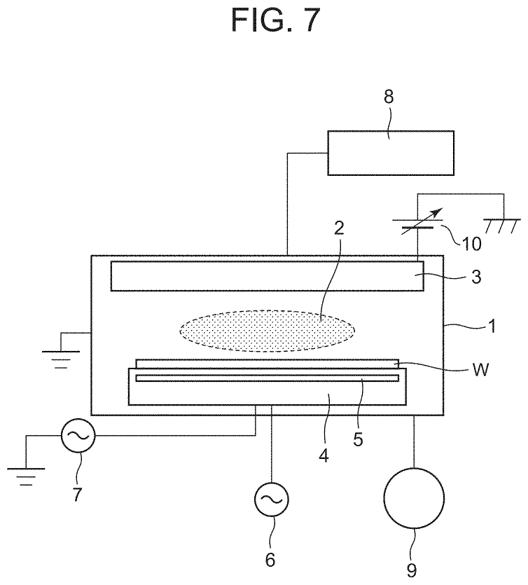

In the first step, the substrate W which includes, for example, a first region and a second region is placed on a substrate support in a chamber 1 of a substrate processing apparatus (for example, the substrate processing apparatus of FIG. 7). The first region includes a silicon oxide film. The second region includes a film other than the silicon oxide film. The film included in the second region may be selected from a silicon-containing film other than a silicon oxide film (e.g., a silicon nitride film, a silicon oxynitride film, a polysilicon film, etc.); a metal-containing film containing a metal such as titanium (Ti), tungsten (W), ruthenium (Ru), or molybdenum (Mo); and an organic film. The metal-containing film may specifically contain TiN or RuO₂. In an exemplary embodiment, the substrate W may include a patterned mask MK. The mask MK may be formed from an organic film such as a photoresist film or a spin-on-carbon (SOC) film; or a metal-containing film containing, for example, titanium nitride (TiN).

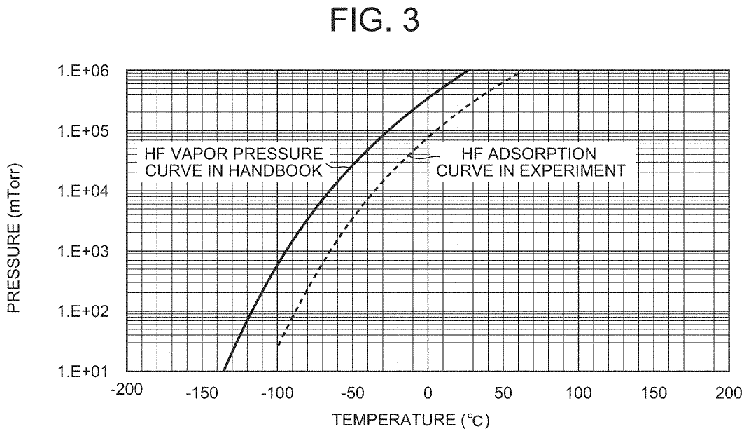

In the second step, the HF adsorption phase shown in FIG. 2A, HF is adsorbed on the substrate W. In an exemplary embodiment, an HF gas is supplied into the chamber 1 to expose the substrate W to the HF gas. The HF is thus adsorbed on the surface of the substrate W without plasma generation. In an exemplary embodiment, an inert gas such as Ar may be supplied, in addition to the HF gas. The HF is adsorbed on the surface of the substrate W under a controlled pressure in the chamber 1 (partial pressure of the HF gas when a mixture of the HF gas and other gas(es) is supplied) and a controlled surface temperature of the substrate support (e.g., ESC). The surface temperature of the substrate support is controlled to, for example, 0° C. or lower (e.g., between −170° C. and 0° C.), or −40 ° C. or lower (e.g., between −40° C. and 0° C.). In an exemplary embodiment, the surface temperature of the substrate support is controlled to be, for example, between −100° C. and 60° C. (see FIG. 3). HF gas is absorbed in the region on the left side (low temperature side of the dotted line in FIG. 3.

In the third step, the etching phase, the substrate W having the adsorbed HF is substantially exposed to plasma generated from the inert gas to cause the first region (which includes the silicon oxide film) to react with the HF. This allows the first region to be etched selectively with respect to the second region. The inert gas may contain a noble gas such as Ar, Kr or Xe or a nitrogen gas. The RF for generating the plasma may be set so as to not damage the second region. For example, the RF may be 100 V_{DC}. FIG. 7 shows the plasma 2 formed in the chamber 1.

This method enables highly selective etching equivalent to that achieved with Atomic Layer Epitaxy (ALE). The method either eliminates or reduces the use of any deposition gas such as a fluorocarbon gas (CF gas), thus reducing possible clogging. The method is also effective at low ESC temperature (e.g., −70° C.). The method further reduces deposits in the chamber 1 and lowers the frequency of cleaning that is to be performed, thus improving the processing throughput.

FIG. 2B is an exemplary graph showing a gas flow and RF power relationship versus time used in the process of FIG. 2A. As seen in FIG. 2B, the HF gas is on when the Ar gas is off, and the Ar gas is on when the HF gas is off. The RF power is supplied during the same periods that the Ar gas is on. Exemplary processing conditions during the HF adsorption phase are a chamber pressure of 350 mTorr, 0 W RF power for plasma generation, 0 W RF power for biasing, ESC temperature −70° C., and a processing time of 10 seconds. A substrate W having a size of 300 mm diameter can be used with the above exemplary processing conditions. In an exemplary embodiment, Ar gas may be supplied continuously throughout the HF adsorption phase and the etching phase. In an exemplary embodiment, the chamber pressure during the HF adsorption phase can be between 1 mTorr and 1,000,000 mTorr (see FIG. 3). Exemplary processing conditions during the etching phase are a chamber pressure of 350 mTorr, 500 W RF power for plasma generation, 0 W RF power for biasing, ESC temperature −70° C., and a processing time of 10 seconds.

FIG. 2C is an exemplary graph showing a relationship between a number of etch cycles and the etch amount for the process of FIG. 2A. In FIG. 2C, the solid line is for the silicon oxide film and the dashed line is for the silicon nitride film. The silicon nitride has a natural oxide film that has a thickness of 1.7 nm. After 15 etch cycles, the etched amount of silicon oxide is 28.9 nm, while the etched amount of silicon nitride is 4.3 nm (1.7 nm of the natural oxide film and an additional 2.6 nm after the natural oxide film is removed). As seen by the solid line in FIG. 2C, between 0 and 8 etch cycles, more silicon oxide material is removed per etch cycle than in the ninth etch cycle and greater. In an exemplary embodiment, the number of cycles in the process is 50. In an exemplary embodiment, the number of cycles in the process is between 40 and 60. However, the number of cycles can be any number.

FIG. 3 is an exemplary graph showing an HF absorption curve produced during an experiment in comparison to HF absorption curve data from a manual or handbook. The vertical axis of the graph is pressure in mTorr, and the horizontal axis is temperature in Celsius. The solid line is a boundary line for which HF adsorption occurs in the absorption phase based on data from a manual or handbook. In the graph, based on the solid curve obtained from the data from the manual or handbook, adsorption should occur at pressures and temperatures to the left side of the curve. In the graph, the solid line is an HF absorption curve produced during an experiment. As this curve is shifted to the right on the graph, it can be seen that adsorption may occur at higher temperatures during actual use than those indicated by the manual or handbook. One data point for adsorption on the dashed line is −70° C. and a pressure of 350 mTorr.

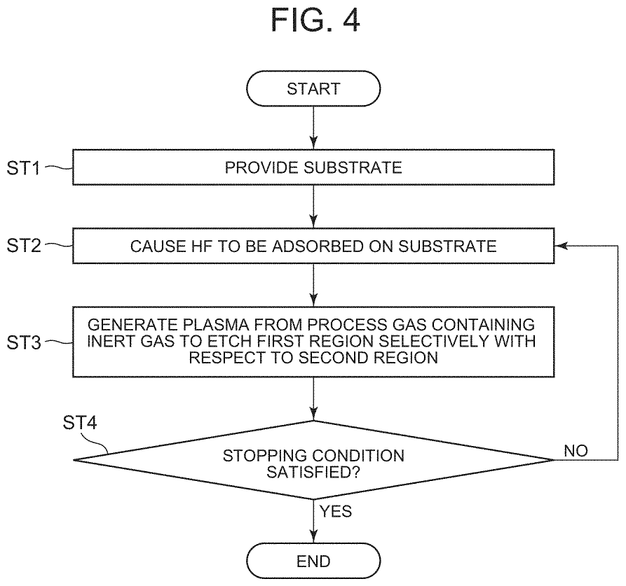

FIG. 4 is a flowchart illustrating a method in accordance with an exemplary embodiment. The first step of the method, ST1, is that the substrate W is provided and is positioned in the processing chamber 1 of the substrate processing apparatus. In the second step, ST2, HF gas is adsorbed on the substrate W. In step three, ST3, plasma 2 is generated from process gas containing inert gas, which selectively etches the first region (including a silicon oxide film) with respect to the second region (including a film other than silicon oxide). In the fourth step, ST4, it is determined whether a stopping condition is satisfied. In an exemplary embodiment, the stopping condition can be a desired depth of the etching. When the stopping condition is satisfied, the method ends and processing on the substrate W is finished. When the stopping condition is not satisfied, the process starts again at step ST2 and loops until the stopping condition is satisfied.

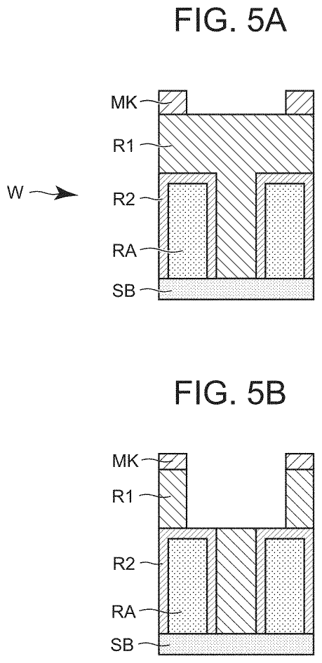

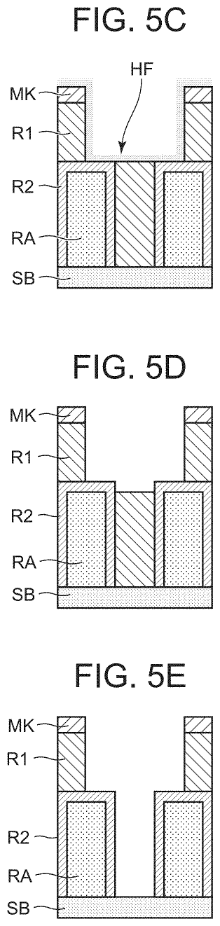

FIG. 5A illustrates a state of an exemplary substrate W during the method of FIG. 4. Specifically, FIG. 5A shows a substrate W that is provided and positioned in the chamber 1 during step ST1 in FIG. 4. The bottom layer is a substrate SB, and this is defined as the bottom as the substrate SB is in contact with the ESC, and other layers of the substrate are located above layer SB. Located above the substrate SB is a raised region RA and the second region R2. Located above the second region R2 is the first region R1. The first region R1 includes a silicon oxide film. The second region R2 includes a film other than the silicon oxide film. The film included in the second region R2 is selected from a silicon-containing film other than the silicon oxide film (e.g., a silicon nitride film, a silicon oxynitride film, or a polysilicon film); a metal-containing film containing a metal such as titanium or tungsten; and an organic film. The substrate W may include a patterned mask MK. The mask MK may be formed from an organic film such as a photoresist film or an SOC film; or a metal-containing film containing, for example, TiN. As seen in FIG. 5A, there are two areas that have the raised region RA and the second region R2. The second region R2 partially surrounds the raised region RA. The first region R1 has a T-shape, and is located in between the two areas having the raised region RA and the second region R2. The first region is also present above the two areas having the raised region RA and the second region R2, and extends across the width of the substrate SB.

FIG. 5B illustrates a state of the exemplary substrate W during the method of FIG. 4. Specifically, the first region R1 is etched until the second region R2 is exposed, or until immediately before the second region R2 is exposed. In an exemplary embodiment, a known method can be used for this etching process.

FIG. 5C illustrates a state of the exemplary substrate W during the method of FIG. 4. Specifically, FIG. 5C illustrates a state of the substrate W during step ST2 of FIG. 4. During ST2, HF is adsorbed on the substrate surface (i.e., upper surface). In one example, an HF gas is supplied under the surface temperature of a substrate support being controlled to −40° C. or lower. The HF is thus adsorbed on the substrate surface without plasma generation.

FIG. 5D illustrates a state of the exemplary substrate W during the method of FIG. 4. Specifically, FIG. 5D illustrates a state of the substrate W during step ST3 of FIG. 4. During ST3, the substrate is exposed to plasma generated from an inert gas to cause the first region R1 to react with the HF adsorbed on the substrate surface. This allows the first region R1 to be etched selectively with respect to the second region R2, as seen in FIG. 5D.

FIG. 5E illustrates a state of the exemplary substrate W during the method of FIG. 4. The sequence of steps of ST2 and ST3 is repeated until the stopping condition is satisfied (ST4 in FIG. 4). As seen in FIG. 5E, the middle portion of the first region R1 has been selectively etched away by several etch cycles. The other portions of the substrate W remain intact.

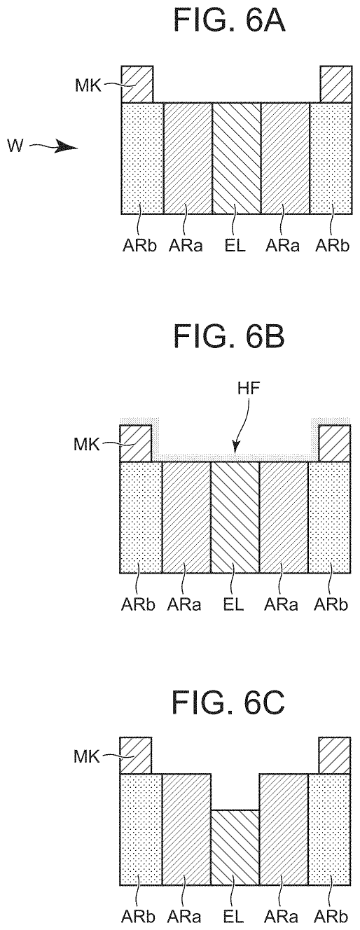

FIG. 6A illustrates a beginning state of another different exemplary substrate W during the method of FIG. 4. In step ST1 of FIG. 4, this substrate W is provided and positioned in the chamber 1. The etching target region EL (first region) includes a silicon oxide film. The regions ARa and ARb (second regions) include films other than the silicon oxide film. In an exemplary embodiment, the films other than the silicon oxide film are selected from a silicon-containing film (e.g., a silicon nitride film, a silicon oxynitride film, or a polysilicon film); a metal-containing film containing a metal such as titanium or tungsten; and an organic film. Similar to the regions ARa and ARb, the mask MK may be formed from a silicon-containing film other than the silicon oxide film; a metal-containing film; or an organic film. As seen in FIG. 6A, the etching target region EL is located in the middle of the substrate W. The regions ARa are located on each side of the etching target region EL. The regions ARb are the outer regions, and regions ARa and etching target region EL are in between the two regions ARb.

FIG. 6B illustrates a state of this other exemplary substrate W during step ST2 of the method of FIG. 4. During this step, HF gas is adsorbed on the substrate surface (i.e., the upper surface of the substrate W). In an exemplary embodiment, an HF gas is supplied under the surface temperature of a substrate support being controlled to −40° C. or lower. During this step, the HF is adsorbed on the substrate surface without plasma generation.

FIG. 6C illustrates a state of this other exemplary substrate W during steps ST3 and ST4 of the method of FIG. 4. The substrate W is exposed to plasma generated from an inert gas to cause the etching target film EL to react with the HF adsorbed on the substrate surface (ST3 in FIG. 4). This allows the etching target region EL to be etched selectively with respect to the regions ARa and ARb. The sequence including ST2 and ST3 is then repeated until the stopping condition is satisfied (ST4 in FIG. 4).

FIG. 7 illustrates an exemplary capacitively coupled plasma (CCP) type plasma system that can be used to perform the substrate processing described herein. The system of FIG. 7 includes a chamber 1, an upper electrode 3, and a lower electrode 4. RF power is coupled to the lower electrode 4 from RF sources 6 and 7. The RF source 6 may be configured to supply RF power for plasma generation. The RF power may have a frequency ranging from 27 MHz to 100 MHZ, for example, 40 MHz. The RF power may be a continuous wave or a pulsed wave. The RF source 6 may be coupled to the upper electrode 3 instead of the lower electrode 4. The RF source 7 may be configured to supply RF bias power for ion attraction into the substrate W. The RF bias power may have a frequency ranging from 400 kHz to 13.56 MHz, for example, 400 kHz The RF bias power may be a continuous wave or a pulsed wave. The lower electrode 4 includes an ESC 5 to support and retain a substrate W. A gas source 8 is connected to the chamber 1 to supply processing gases into the chamber 1. An exhaust device 9 such as a turbo molecular pump (TMP) is connected to the chamber 1 to evacuate the chamber 1. Plasma 2 is formed proximate to the substrate W between the upper electrode 3 and the lower electrode 4 as the RF power is supplied to the lower electrode 4. Alternatively, multiple RF power sources 6 and 7 may be coupled to a different electrode (e.g., upper electrode 3). Moreover, a variable direct current (DC) power source 10 may be coupled to the upper electrode 3.

A pulse power source may be used instead of the RF source 7. The pulse power source is configured to supply a pulsed voltage other than RF power for ion attraction into the substrate W. The pulse power source may provide pulsed waves or may include a device for pulsing the voltage downstream from the pulse power supply. In one example, a pulsed voltage is applied to the lower electrode 4 to cause the substrate W to have a negative potential. The pulsed voltage may be a pulsed negative DC voltage. The pulsed voltage may have a square wave pulse, a triangular wave pulse, an impulse, or any other voltage waveform pulse.

In an exemplary embodiment, in the CCP type plasma processing apparatus shown in FIG. 7, the lower electrode 4 is provided with RF power for plasma generation. In an exemplary embodiment, the upper electrode 3 may be provided with RF power. The processing methods disclosed herein are also applicable to a plasma processing apparatus different from the CCP plasma processing apparatus. More specifically, the processing methods may be implemented using any plasma processing apparatus, such as an inductively coupled plasma processing apparatus, a plasma processing apparatus that generates plasma using surface waves such as microwaves, etc.

Control methods and systems described herein may be implemented using computer programming or engineering techniques including computer software, firmware, hardware or any combination or subset thereof, wherein the technical effects may include at least processing of a substrate in a plasma processing apparatus according to the present disclosure.

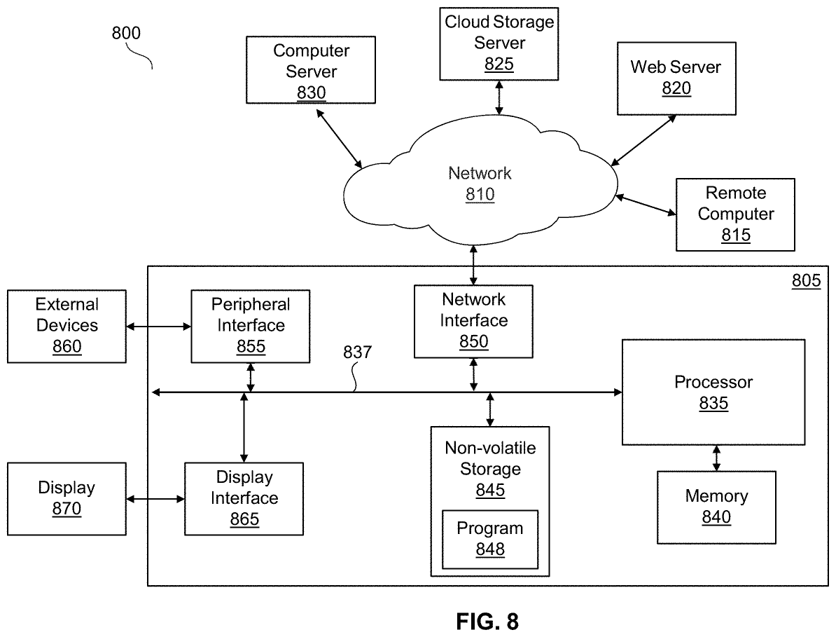

FIG. 8 illustrates a block diagram of a computer that may implement the various embodiments described herein.

Control aspects of the present disclosure may be embodied as a system, a method, and/or a computer program product. The computer program product may include a computer readable storage medium on which computer readable program instructions are recorded that may cause one or more processors to carry out aspects of the embodiment.

The computer readable storage medium may be a tangible device that can store instructions for use by an instruction execution device (processor). The computer readable storage medium may be, for example, but is not limited to, an electronic storage device, a magnetic storage device, an optical storage device, an electromagnetic storage device, a semiconductor storage device, or any appropriate combination of these devices. A non-exhaustive list of more specific examples of the computer readable storage medium includes each of the following (and appropriate combinations): flexible disk, hard disk, solid-state drive (SSD), random access memory (RAM), read-only memory (ROM), erasable programmable read-only memory (EPROM or Flash), static random access memory (SRAM), compact disc (CD or CD-ROM), digital versatile disk (DVD) and memory card or stick. A computer readable storage medium, as used in this disclosure, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described in this disclosure can be downloaded to an appropriate computing or processing device from a computer readable storage medium or to an external computer or external storage device via a global network (i.e., the Internet), a local area network, a wide area network and/or a wireless network. The network may include copper transmission wires, optical communication fibers, wireless transmission, routers, firewalls, switches, gateway computers and/or edge servers. A network adapter card or network interface in each computing or processing device may receive computer readable program instructions from the network and forward the computer readable program instructions for storage in a computer readable storage medium within the computing or processing device.

Computer readable program instructions for carrying out operations of the present disclosure may include machine language instructions and/or microcode, which may be compiled or interpreted from source code written in any combination of one or more programming languages, including assembly language, Basic, Fortran, Java, Python, R, C, C++, C# or similar programming languages. The computer readable program instructions may execute entirely on a user's personal computer, notebook computer, tablet, or smartphone, entirely on a remote computer or computer server, or any combination of these computing devices. The remote computer or computer server may be connected to the user's device or devices through a computer network, including a local area network or a wide area network, or a global network (i.e., the Internet). In some embodiments, electronic circuitry including, for example, programmable logic circuitry, field-programmable gate arrays (FPGA), or programmable logic arrays (PLA) may execute the computer readable program instructions by using information from the computer readable program instructions to configure or customize the electronic circuitry, in order to perform aspects of the present disclosure.

Aspects of the present disclosure are described herein with reference to flow diagrams and block diagrams of methods, apparatus (systems), and computer program products according to embodiments of the disclosure. It will be understood by those skilled in the art that each block of the flow diagrams and block diagrams, and combinations of blocks in the flow diagrams and block diagrams, can be implemented by computer readable program instructions.

The computer readable program instructions that may implement the systems and methods described in this disclosure may be provided to one or more processors (and/or one or more cores within a processor) of a general purpose computer, special purpose computer, or other programmable apparatus to produce a machine, such that the instructions, which execute via the processor of the computer or other programmable apparatus, create a system for implementing the functions specified in the flow diagrams and block diagrams in the present disclosure. These computer readable program instructions may also be stored in a computer readable storage medium that can direct a computer, a programmable apparatus, and/or other devices to function in a particular manner, such that the computer readable storage medium having stored instructions is an article of manufacture including instructions which implement aspects of the functions specified in the flow diagrams and block diagrams in the present disclosure.

The computer readable program instructions may also be loaded onto a computer, other programmable apparatus, or other device to cause a series of operational steps to be performed on the computer, other programmable apparatus or other device to produce a computer implemented process, such that the instructions which execute on the computer, other programmable apparatus, or other device implement the functions specified in the flow diagrams and block diagrams in the present disclosure.

FIG. 8 is a functional block diagram illustrating a networked system 800 of one or more networked computers and servers. In an embodiment, the hardware and software environment illustrated in FIG. 8 may provide an exemplary platform for implementation of the software and/or methods according to the present disclosure.

Referring to FIG. 8, a networked system 800 may include, but is not limited to, computer 805, network 810, remote computer 815, web server 820, cloud storage server 825 and computer server 830. In some embodiments, multiple instances of one or more of the functional blocks illustrated in FIG. 8 may be employed.

Additional detail of computer 805 is shown in FIG. 8. The functional blocks illustrated within computer 805 are provided only to establish exemplary functionality and are not intended to be exhaustive. And while details are not provided for remote computer 815, web server 820, cloud storage server 825 and computer server 830, these other computers and devices may include similar functionality to that shown for computer 805.

Computer 805 may be a personal computer (PC), a desktop computer, laptop computer, tablet computer, netbook computer, a personal digital assistant (PDA), a smart phone, or any other programmable electronic device capable of communicating with other devices on network 810.

Computer 805 may include processor 835, bus 837, memory 840, non-volatile storage 845, network interface 850, peripheral interface 855 and display interface 865. Each of these functions may be implemented, in some embodiments, as individual electronic subsystems (integrated circuit chip or combination of chips and associated devices), or, in other embodiments, some combination of functions may be implemented on a single chip (sometimes called a system on chip or SoC).

Processor 835 may be one or more single or multi-chip microprocessors, such as those designed and/or manufactured by Intel Corporation, Advanced Micro Devices, Inc. (AMD), Arm Holdings (Arm), Apple Computer, etc. Examples of microprocessors include Celeron, Pentium, Core i3, Core i5 and Core i7 from Intel Corporation; Opteron, Phenom, Athlon, Turion and Ryzen from AMD; and Cortex-A, Cortex-R and Cortex-M from Arm.

Bus 837 may be a proprietary or industry standard high-speed parallel or serial peripheral interconnect bus, such as ISA, PCI, PCI Express (PCI-e), AGP, and the like.

Memory 840 and non-volatile storage 845 may be computer-readable storage media. Memory 840 may include any suitable volatile storage devices such as Dynamic Random Access Memory (DRAM) and Static Random Access Memory (SRAM). Non-volatile storage 845 may include one or more of the following: flexible disk, hard disk, solid-state drive (SSD), read-only memory (ROM), erasable programmable read-only memory (EPROM or Flash), compact disc (CD or CD-ROM), digital versatile disk (DVD) and memory card or stick.

Program 848 may be a collection of machine readable instructions and/or data that is stored in non-volatile storage 845 and is used to create, manage and control certain software functions that are discussed in detail elsewhere in the present disclosure and illustrated in the drawings. In some embodiments, memory 840 may be considerably faster than non-volatile storage 845. In such embodiments, program 848 may be transferred from non-volatile storage 845 to memory 840 prior to execution by processor 835.

Computer 805 may be capable of communicating and interacting with other computers via network 810 through network interface 850. Network 810 may be, for example, a local area network (LAN), a wide area network (WAN) such as the Internet, or a combination of the two, and may include wired, wireless, or fiber optic connections. In general, network 810 can be any combination of connections and protocols that support communications between two or more computers and related devices.

Peripheral interface 855 may allow for input and output of data with other devices that may be connected locally with computer 805. For example, peripheral interface 855 may provide a connection to external devices 860. External devices 860 may include devices such as a keyboard, a mouse, a keypad, a touch screen, and/or other suitable input devices. External devices 860 may also include portable computer-readable storage media such as, for example, thumb drives, portable optical or magnetic disks, and memory cards. Software and data used to practice embodiments of the present disclosure, for example, program 848, may be stored on such portable computer-readable storage media. In such embodiments, software may be loaded onto non-volatile storage 845 or, alternatively, directly into memory 840 via peripheral interface 855. Peripheral interface 855 may use an industry standard connection, such as RS-232 or Universal Serial Bus (USB), to connect with external devices 860.

Display interface 865 may connect computer 805 to display 870. Display 870 may be used, in some embodiments, to present a command line or graphical user interface to a user of computer 805. Display interface 865 may connect to display 870 using one or more proprietary or industry standard connections, such as VGA, DVI, DisplayPort and HDMI.

As described above, network interface 850, provides for communications with other computing and storage systems or devices external to computer 805. Software programs and data discussed herein may be downloaded from, for example, remote computer 815, web server 820, cloud storage server 825 and computer server 830 to non-volatile storage 845 through network interface 850 and network 810. Furthermore, the systems and methods described in this disclosure may be executed by one or more computers connected to computer 805 through network interface 850 and network 810. For example, in some embodiments the systems and methods described in this disclosure may be executed by remote computer 815, computer server 830, or a combination of the interconnected computers on network 810.

Data, datasets and/or databases employed in embodiments of the systems and methods described in this disclosure may be stored and or downloaded from remote computer 815, web server 820, cloud storage server 825 and computer server 830.

In an exemplary embodiment, for very deep etches the computer 805 will allow for variation of the waveform shown in FIG. 2B. That is, the duty cycle can be varied for very deep etches by changing the ratios of period (1) and period (2) in FIG. 2B.

In an exemplary embodiment, a method includes providing a substrate W in a process chamber 1 of a substrate processing apparatus, the substrate W having a first region (e.g., region R1 in FIG. 5A) containing a silicon oxide film and a second region (e.g., region R2 in FIG. 5A) containing a film other than the silicon oxide film. The method further includes adsorbing HF on the substrate W, and exposing the substrate W with the absorbed HF to plasma 2 generated from an inert gas to selectively etch the first region with respect to the second region. In an exemplary embodiment, the inert gas is a noble gas. In an exemplary embodiment, the inert gas is Argon or a Nitrogen gas.

In an exemplary embodiment, the substrate W absorbs the HF without plasma generation.

In an exemplary embodiment, the method further includes controlling temperature in the process chamber 1 during the absorbing of the HF on the substrate W. In an exemplary embodiment, the pressure is controlled to be 350 mTorr or more. In an exemplary embodiment, the temperature is controlled to be 0° C. or less.

In an exemplary embodiment, the absorbing of HF on the substrate W and the exposing the substrate W with the absorbed HF to plasma generated from an inert gas are repeated at least once. In an exemplary embodiment, after the absorbing of HF on the substrate W and the exposing the substrate W with the absorbed HF to plasma generated from an inert gas are repeated 15 times, an etch amount of the second region is less than 15 percent of an etch amount of the first region.

In an exemplary embodiment, the substrate W is supported by an ESC 5, and the method further includes controlling a surface temperature of the ESC 5 to be equal to or less than 0° C., or equal to or less than −40° C. In an exemplary embodiment the method includes controlling a surface temperature of the ESC 5 to be less than or equal to 0° C. and greater than or equal to −170° C.

In an exemplary embodiment, the method includes continuously supplying the inert gas throughout a process of the absorbing of the HF in addition to a process of the exposing of the substrate W to the plasma 2.

In an exemplary embodiment, RF power used to generate the plasma 2 is 50 Watts to 500 Watts. In an exemplary embodiment, 50 Volts to 100 Volts DC is used to generate the 50 Watts to 500 Watts of RF power.

In an exemplary embodiment, the second region (e.g., R2 in FIG. 5A) includes silicon nitride, silicon oxynitride, polysilicon, a metal, or an organic compound.

In an exemplary embodiment, a substrate processing apparatus (shown, for example, in FIG. 7) is configured to perform processing on a substrate W to modify a condition of the substrate W. The substrate processing apparatus includes a process chamber 1, a substrate support, including an ESC 5, that supports the substrate W having a first region containing a silicon oxide film and a second region containing a film other than the silicon oxide film. The substrate processing apparatus includes processing circuitry (e.g., processor 835) configured to control providing of fluoride inside the process chamber 1 so the substrate W absorbs the HF, and control providing of plasma generated from an inert gas inside the process chamber 1 to expose the substrate W with the absorbed HF to the generated plasma to selectively etch the first region with respect to the second region.

In an exemplary embodiment, the substrate W absorbs the HF without plasma generation.

In an exemplary embodiment, the substrate processing apparatus controls (by, e.g., processor 835) pressure in the process chamber 1 during the absorbing of the HF on the substrate W. In an exemplary embodiment, the pressure is controlled to be 350 mTorr or more.

In an exemplary embodiment, the inert gas is a noble gas. In an exemplary embodiment, the inert gas is Argon or a Nitrogen gas.

Having now described embodiments of the disclosed subject matter, it should be apparent to those skilled in the art that the foregoing is merely illustrative and not limiting, having been presented by way of example only. Thus, although particular configurations have been discussed herein, other configurations can also be employed. Numerous modifications and other embodiments (e.g., combinations, rearrangements, etc.) are enabled by the present disclosure and are within the scope of one of ordinary skill in the art and are contemplated as falling within the scope of the disclosed subject matter and any equivalents thereto. Features of the disclosed embodiments can be combined, rearranged, omitted, etc., within the scope of the invention to produce additional embodiments. Furthermore, certain features may sometimes be used to advantage without a corresponding use of other features. Accordingly, Applicant(s) intend(s) to embrace all such alternatives, modifications, equivalents, and variations that are within the spirit and scope of the disclosed subject matter.

1. A method comprising:
providing a substrate in a process chamber of a substrate processing apparatus, the substrate having a first region containing a silicon oxide film and a second region containing a film other than the silicon oxide film;
adsorbing hydrogen fluoride on the substrate; and
exposing the substrate with the absorbed hydrogen fluoride to plasma generated from an inert gas to selectively etch the first region with respect to the second region.

2. The method of claim 1, wherein the substrate absorbs the hydrogen fluoride without plasma generation.

3. The method of claim 1, further comprising:
controlling temperature in the process chamber during the absorbing of the hydrogen fluoride on the substrate.

4. The method of claim 3, wherein the temperature is controlled to be 0° C. or less.

5. The method of claim 1, wherein the inert gas is a noble gas.

6. The method of claim 1, wherein the inert gas is Argon or a Nitrogen gas.

7. The method of claim 1, wherein the absorbing of hydrogen fluoride on the substrate and the exposing the substrate with the absorbed hydrogen fluoride to plasma generated from an inert gas are repeated at least once.

8. The method of claim 7, wherein after the absorbing of hydrogen fluoride on the substrate and the exposing the substrate with the absorbed hydrogen fluoride to plasma generated from an inert gas are repeated 15 times, an etch amount of the second region is less than 15 percent of an etch amount of the first region.

9. The method of claim 1, wherein the substrate is supported by an electrostatic chuck (ESC), and the method further comprises controlling a surface temperature of the ESC to be equal to or less than 0° C., or equal to or less than −40° C.

10. The method of claim 1, wherein the substrate is supported by an ESC, and the method further comprises controlling a surface temperature of the ESC to be less than or equal to 0° C. and greater than or equal to −170° C.

11. The method of claim 1, further comprising:
continuously supplying the inert gas throughout a process of the absorbing of the hydrogen fluoride in addition to a process of the exposing of the substrate to the plasma.

12. The method of claim 1, radio frequency power used to generate the plasma is 50 Watts to 500 Watts.

13. The method of claim 12, wherein 50 Volts to 100 Volts DC is used to generate the 50 Watts to 500 Watts of radio frequency power.

14. The method of claim 1, wherein the second region includes silicon nitride, silicon oxynitride, polysilicon, a metal, or an organic compound.

15. A substrate processing apparatus configured to perform processing on a substrate to modify a condition of the substrate, the substrate processing apparatus comprising:
a process chamber,
a substrate support, including an ESC, that supports a substrate having a first region containing a silicon oxide film and a second region containing a film other than the silicon oxide film; and
processing circuitry configured to
control providing of fluoride inside the process chamber so the substrate absorbs the hydrogen fluoride, and
control providing of plasma generated from an inert gas inside the process chamber to expose the substrate with the absorbed hydrogen fluoride to the generated plasma to selectively etch the first region with respect to the second region.

16. The substrate processing apparatus of claim 15, wherein the substrate absorbs the hydrogen fluoride without plasma generation.

17. The substrate processing apparatus of claim 15, further comprising:
controlling pressure in the process chamber during the absorbing of the hydrogen fluoride on the substrate.

18. The substrate processing apparatus of claim 17, wherein the pressure is controlled to be 350 mTorr or more.

19. The substrate processing apparatus of claim 15, wherein the inert gas is a noble gas.

20. The substrate processing apparatus of claim 15, wherein the inert gas is Argon or a Nitrogen gas.
